(19) United States
(12) Patent Application Publication
(10) Pub. No.: US 2013/0316512 A1
(43) Pub. Date: Nov. 28, 2013

(54) SEMICONDUCTOR WIRE-ARRAY VARACTOR STRUCTURES

(71) Applicants: Oki Gunawan, Fair Lawn, NJ (US); Amlan Majumdar, White Plains, NY (US); Katherine L. Saenger, Ossining, NY (US)

(72) Inventors: Oki Gunawan, Fair Lawn, NJ (US); Amlan Majumdar, White Plains, NY (US); Katherine L. Saenger, Ossining, NY (US)

(73) Assignee: INTERNATIONAL BUSINESS MACHINES CORPORATION, Armonk, NY (US)

(21) Appl. No.: 13/495,148

(22) Filed: Jun. 13, 2012

Related U.S. Application Data
(63) Continuation of application No. 13/479,871, filed on May 24, 2012.

(51) Int. Cl. H01L 49/02

(52) U.S. Cl. CPC H01L 28/40
USPC 438/396

(57) ABSTRACT

Semiconductor variable capacitor (varactor) devices are provided, which are formed with an array of radial p-n junction structures to provide improved dynamic range and sensitivity. For example, a semiconductor varactor device includes a doped semiconductor substrate having first and second opposing surfaces and an array of pillar structures formed on the first surface of the doped semiconductor substrate. Each pillar structure includes a radial p-n junction structure. A first metallic contact layer is conformally formed over the array of pillar structures on the first surface of the doped semiconductor substrate. A second metallic contact layer formed on the second surface of the doped semiconductor substrate. An insulating layer is formed on the doped semiconductor substrate surrounding the array of pillar structures.

### CROSS-REFERENCE TO RELATED APPLICATION

This application is a Continuation of U.S. patent application Ser. No. 13/479,871, filed on May 24, 2012, the disclosure of which is fully incorporated herein by reference.

### TECHNICAL FIELD

The field generally relates to semiconductor variable capacitor (varactor) devices and, more particularly, to semiconductor varactor devices that are formed with an array of radial p-n junction structures to provide improved dynamic range and sensitivity.

### BACKGROUND

Variable capacitance diodes or variable reactance diodes (varactors) are semiconductor devices that are employed in many applications that require a tunable oscillator such as a radio tuner, a VCO (voltage-controlled oscillator) in phase-locked loops, frequency synthesizers, parametric amplifiers, and parametric oscillators. A conventional varactor device is formed as a planar p-n junction diode, where an applied reverse bias voltage will increase the thickness of the dielectric depletion region and thus change the capacitance. A conventional planar varactor device, however, has a limited capacitance per unit area and has a limited dynamic range, wherein the dynamic range is a ratio of maximum (C_{MAX}) achievable capacitance to a minimum (C_{MIN}) achievable capacitance, i.e., C_{MAX}/C_{MIN}.

For example, a conventional planar varactor device typically has a dynamic range of about 2.5 to about 6. Moreover, a conventional planar varactor device practically has only one adjustable design parameter i.e. the doping profile in a lower-doped region of the diode, to tailor the dynamic range. However, the use of doping profile to control dynamic range of a planar varactor device is very demanding and is typically achieved using an expensive ion implantation process.

### SUMMARY

Aspects of the invention include semiconductor variable capacitor (varactor) devices that are formed with an array of radial p-n junction structures to provide improved dynamic range and sensitivity.

In one aspect of the invention, a semiconductor varactor device includes a doped semiconductor substrate having first and second opposing surfaces and an array of pillar structures formed on the first surface of the doped semiconductor substrate. Each pillar structure includes a radial p-n junction structure. A first metallic contact layer is conformally formed over the array of pillar structures on the first surface of the doped semiconductor substrate. A second metallic contact layer formed on the second surface of the doped semiconductor substrate. An insulating layer is formed on the doped semiconductor substrate surrounding the array of pillar structures.

In another aspect of the invention, the pillar structures are cylindrical shaped having a diameter d and a height h. The parameters d and h are selectively dimensioned to tune capacitance-voltage characteristics of the semiconductor varactor device. For instance, a sensitivity characteristic of the varactor device is tunable based on the parameter h, and a dynamic range characteristic of the varactor device is tunable based on the parameter d.

These and other aspects, features and advantages of the present invention will become apparent from the following detailed description of preferred embodiments thereof, which is to be read in connection with the accompanying drawings.

### BRIEF DESCRIPTION OF THE DRAWINGS

FIG. 1 is a cross-sectional view of a varactor device comprising an array of radial p-n junction structures according to an aspect of the invention.

FIG. 2 is a schematic top view of a varactor device having an array of radial p-n junction in a honeycomb arrangement according to an aspect of the invention.

FIG. 3 is a perspective view of a geometric model of one unit cell of a varactor device according to an aspect of the invention.

FIG. 4 is a C-V (capacitance vs. voltage) graph that illustrates operational principles of a varactor device according to an aspect of the invention.

FIG. 5 are C-V curves that illustrate dynamic range control of a varactor device for different height values based on the unit cell geometric model of FIG. 3.

FIG. 6 shows C-V curves that illustrate sensitivity control of a varactor device for different radius values based on the unit cell geometric model of FIG. 3.

FIG. 7 shows scanning electron microscope images of varactor devices fabricated using deep-UV lithography and self-assembled microsphere lithography.

FIG. 8 is a flow diagram illustrating a method for fabricating a varactor device according to an aspect of the invention.

FIGS. 9A, 9B, 9C, 9D, and 9E illustrate an exemplary methodology for fabricating a wire array varactor device using a self-assembled nano/microsphere lithography process according to an aspect of the invention, wherein,

FIG. 9A a cross-sectional view of a semiconductor wire-array varactor device at an initial stage of fabrication where a monolayer of spheres is deposited on a substrate,

FIG. 9B is a top schematic view of FIG. 9A, showing an arrangement of the monolayer of spheres deposited on the substrate,

FIG. 9C is a cross-sectional view of the structure of FIG. 9A after trimming the spheres in the monolayer to introduce space between the individual spheres,

FIG. 9D is a cross-sectional view of the structure of FIG. 9C after etching the substrate using the trimmed spheres as a mask form vertical wires on the substrate surface, and

FIG. 9E is a cross-sectional view of the structure of FIG. 9D after performing a cleaning process to remove residual portions of the trimmed spheres.

### DETAILED DESCRIPTION OF PREFERRED EMBODIMENTS

Preferred embodiments of the invention will now be described in further detail with regard to semiconductor varactor devices that are formed with an array of radial diode structures to provide improved dynamic range and sensitivity. More specifically, aspects of the invention include a varactor device (alternatively referred to as a “wire-array varactor diode”) comprising an array of radial p-n junction diodes having micron-scale or sub-micron scale diameters. A wire-array varactor diode comprises radial p-n junction structures that are formed as part of an array of free-standing wires or pillars etched or grown on a semiconductor material, thereby providing two adjustable geometric design parameters, the height of the wires and the diameter of the wires, in addition to the doping profile found in a conventional planar varactor diode. As explained in further detail below, the height of the wires can be adjusted to control the dynamic range (Cₘₐₓ/Cₘᵢₙ) of a wire-array varactor device, and the diameter of the wires can be adjusted to control the sensitivity range of a capacitance of the wire-array varactor device. The C-V (capacitance-voltage) profile tailored by these geometric features (height and radius of the wires) enables the use of cheaper diffusion-based doping technique (for example using POCl₃ gas diffusion furnace) to form an emitter layer. Moreover, the ability to tune the C-V profile of a wire-array varactor device using these geometric features (height and radius of the wires) provides significant design flexibility for many circuit applications that can be implemented using varactor devices according to aspects of the invention.

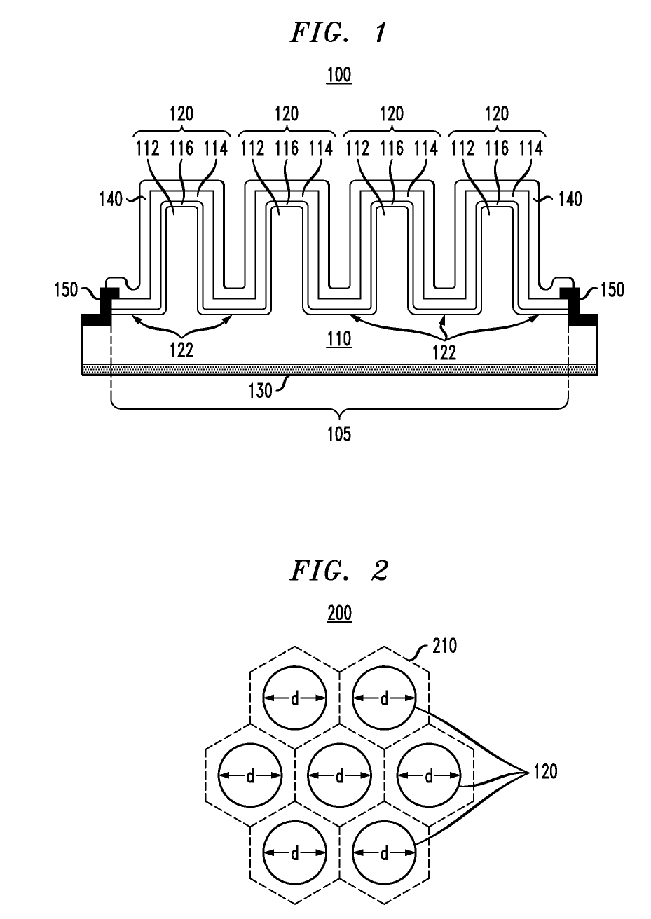

FIG. 1 is a cross-sectional schematic view of a varactor device according to an aspect of the invention. In particular, FIG. 1 schematically illustrates a varactor device 100 comprising a doped semiconductor substrate 110 having an array of pillar structures 120 formed on a first surface of the doped semiconductor substrate 110, wherein each pillar structure 120 comprises a radial p-n junction structure (as discussed below). The semiconductor substrate 110 is doped to have a first conductivity type (e.g., p-type or n-type). The varactor device 100 further comprises a first contact layer 130 (e.g., anode) formed on second surface of the doped semiconductor substrate 110, a second contact layer 140 (e.g., cathode) formed on the array of pillar structures 120, and an insulating layer 150.

The pillar structures 120 provide an array of radial p-n junction structures comprising a plurality of vertical wires 112 (or radial wires) and a conformal semiconductor layer 114 formed over the vertical wires 112 in a defined “mesa’ region 105 of the substrate 110. The vertical wires 112 are semiconductor features that are formed by etching the doped semiconductor substrate 110 or otherwise grown on the surface of the semiconductor substrate 110. The vertical wires 112 are formed of a semiconductor material having a conductivity type that is the same as the conductivity type of the doped semiconductor substrate 110 (e.g., p-type). The conformal semiconductor layer 114 is formed of a semiconductor material having a second conductivity type (e.g., n-type) that is of opposite polarity to the first conductivity type of the semiconductor substrate 110 and the vertical wires 112. As such, a depletion region 116 is formed at the interface between the conformal semiconductor layer 114 and the vertical wires 112 in the pillar structures 120 and between the conformal semiconductor layer 114 and the semiconductor substrate 110 in planar regions 122 between the pillars 120.

In one preferred embodiment of the invention, the doping density of the material forming the conformal semiconductor layer 114 is higher than the doping density of the material forming the vertical wires 112 and the semiconductor substrate 110. For instance, the conformal semiconductor layer 114 may be a highly doped n-type (n⁺) layer, while the substrate 110 and vertical wires 112 are lightly doped p-type (p⁻) layers. This doping configuration ensures that the dielectric depletion region 116 is farmed within the semiconductor material forming the vertical wires 112 (within the pillars 120) and within the semiconductor material of the substrate 110 (in the planar regions 122 between the pillars 120).

The first contact layer 130 and second contact layer 140 may be formed of metallic materials such as aluminum, copper, nickel, titanium, palladium, silver or gold and deposited using techniques such as metal evaporation, electroplating or screen printing. The insulating layer 150 is a passivation layer that is formed on the peripheral edge of the mesa region 105 of the varactor device 100. The insulating layer 150 serves to minimize or prevent leakage of current along the edges of the device 100 and prevent deterioration of the maximum capacitance. The insulating layer 150 may be formed of any suitable insulting/dielectric material such as SiO₂ to minimize the leakage of current along the edges of the mesa region 105 of the varactor device 100.

In one aspect of the invention, the array of pillars 120 may be cylindrical-shaped features that are arranged in a honeycomb lattice array. For instance, FIG. 2 is a schematic top view of a varactor device having an array of radial p-n junction structures 120 (pillar structures) arranged in a honeycomb lattice 210 configuration (as indicted by the dashed lines). The cylindrical pillar structures 120 each have a diameter d which can be in a range of about 0.1 μm to about 20 μm. The pillars 120 maybe formed with other shapes and arranged in other configurations, however, a honeycomb lattice arrangement 210 as shown in FIG. 2 serves to maximize the packing density of the pillars 120 and thus maximize the capacitance per unit area of the varactor device. Depending on the application, a given varactor device may include millions of pillar structures. For example, assuming single pillar structure (a unit cell) has a unit area of 1 μm×1 μm, a varactor diode device having a total area of 1 mm×1 mm would consist of a million pillar structures. The total capacitance of a varactor device according to principles of the invention will scale with the total area, the larger the area the larger the capacitance depending on the requirement or application.

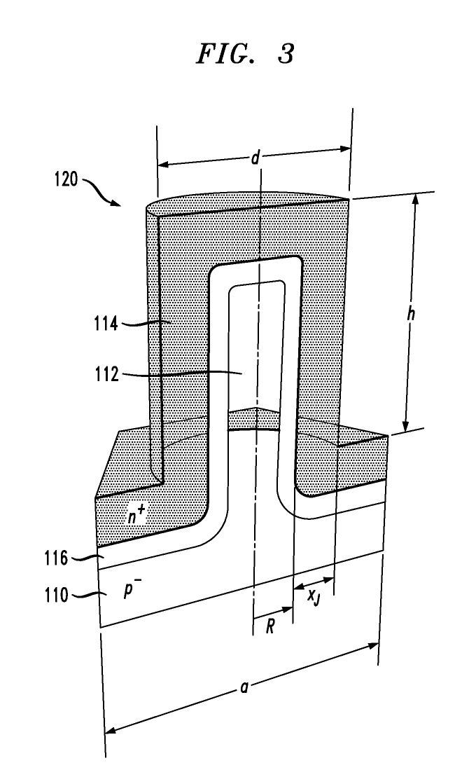

It is to be appreciated that varactor architectures according to aspects of the invention have various design parameters that can be adjusted to tune the C-V (capacitance-voltage) characteristics of a varactor device. In general, a varactor device framework according to principles of the invention provides two adjustable geometric design parameters, which generally include the height and diameter of the pillar structures. In addition, similar to conventional planar varactor devices, the C-V characteristics of a varactor device according to an exemplary embodiment of the invention can be adjusted by a doping profile. Advantageously, the C-V profile tailored by the geometry factors alone (height and radius of the wire) enables the use of cheaper diffusion-based doping technique (for example using POCl₃ gas diffusion furnace) to form the top (or emitter) layer, which facilitates further tuning. These design concepts will now be discussed in further detail with reference to FIGS. 3, 4, 5 and 6.

FIG. 3 is a perspective view of a geometric model of one unit cell of a varactor device according to an aspect of the invention. In particular, FIG. 3 is a perspective view of a single cylindrical pillar structure 120 of a varactor device 100 as discussed above with reference to FIGS. 1 and 2. As depicted in FIG. 3, the pillar structure 120 has a diameter d and a height h. The inner vertical wire 112 has a radius R and the conformal semiconductor layer 114 (or emitter layer) has a thickness x_{J}. With a cylindrical pillar structure 120 as shown in FIG. 3, the diameter d of the pillar structure 120 is equal to 2 R+2 x_{J}. The height h of the pillar structure 120 is the length of the vertical sidewall of the conformal semiconductor layer 114. The parameter a is the lattice constant of a unit cell of the pillar structure.

In general, the height h of the pillar structure 120 is a design parameter that can be varied to control the dynamic range of the varactor device and the diameter d of the pillar structure 120 is a design parameter that can be varied to control the sensitivity range of the capacitance. In particular, the maximum capacitance and thus the dynamic range (Cₘₐₓ/Cₘᵢₙ) can be increased by increasing the height h of the pillar structure 120. This increase in the dynamic range allows for the expansion of bandwidth of many circuits utilizing a varactor device according to the invention. Moreover, the sensitivity of the C-V profile of the wire-array varactor diode can be tuned by adjusting the diameter d of the vertical wire 112.

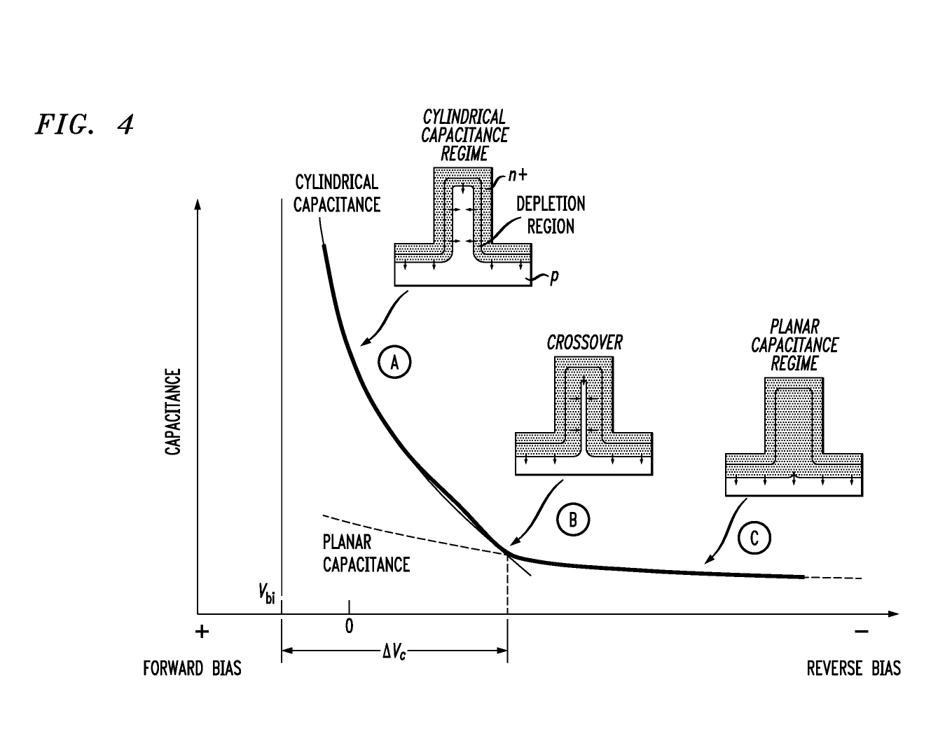

FIG. 4 illustrates operation principles of a varactor device according to an aspect of the invention. In particular, FIG. 4 graphically illustrates capacitance as a function of voltage for a varactor device based on the geometric model depicted in FIG. 3. FIG. 4 depicts various regions of operation including a cylindrical capacitance regime A, a crossover point B, and a planar capacitance regime C. In FIG. 4, a voltage V_{bi} denotes a “built-in voltage” of a varactor device, which is the “built-in” potential that develops across the depletion region in the absence of an external voltage applied to the varactor device, due to the electrostatic charge redistribution at the interface between the p-doped and n-doped layers. The built-in voltage of the p-n junction is given as:

$${V}_{bi} = \frac{kT}{q} ln \frac{{N}_{A} {N}_{D}}{{n}_{i}^{2}} \qquad ( 1 )$$

where k, T and q, are the Boltzmann constant, temperature and the electron charge respectively. N_{A} and N_{D} are the doping level in p⁻ and n⁺ region respectively and nᵢ is the intrinsic carrier density. The formation of the depletion region gives rise to the capacitance of the device.

When the varactor device is biased with voltage that is increasingly smaller than, or more negative than, the built-in voltage V_{bi}, the size of the dielectric depletion region increases between the interface of the n⁺ and the p⁻ region. As the depletion region increases, the capacitance of the varactor device decreases. For example, in FIG. 4, operating region A depicts a low reverse bias region in which the cylindrical capacitance in the pillar structure 120 dominates. In the operating region A, as compared to a conventional planar varactor structure, a wire-array varactor device according to principles of the invention has more capacitance due to the additional area of the cylindrical pillar structures (the cylindrical surface of the vertical wires 112).

In the limit of thin depletion region (small reverse bias), the gain of a wire-array varactor capacitance (C_{W}) over a planar varactor capacitance (C_{P}) is given as (assuming a honeycomb lattice array):

$$\frac{{C}_{W}}{{C}_{P}} = 1 + \frac{4 π Rh}{\sqrt{3} {a}^{2}} \qquad ( 2 )$$

where R, h and a are the wire core radius, height and lattice constant of the array, respectively (see FIG. 3). A higher maximum capacitance (thus higher dynamic range) can be obtained by increasing the height h of the pillar structure 120 and the radius R of the vertical wire 112.

As further depicted in FIG. 4, as the reverse bias across the varactor device increases (becomes more negative), the capacitance decreases as the depletion region 116 becomes thicker. As illustrated in FIG. 4, eventually the varactor device enters operating region C, where the planar capacitance dominates. In operating region C, the vertical wire 112 (within the pillar structure 120) is fully depleted and contributes only a small capacitance. As such, in the operating region C, the C-V curve in FIG. 4 can be viewed as a C-V curve of a standard planar p-n junction capacitance.

Furthermore, as shown in FIG. 4, transition point B marks a transition point between operating regions A and C (i.e., between the cylindrical capacitance regime and the planar capacitance regime). The position of point B relative to the built in voltage V_{bi} is given by ΔV_{C} whose minimum value is given as:

$$Δ {V}_{C , min} = \frac{{qN}_{A} {R}^{2}}{4 ɛ} \qquad ( 3 )$$

where ε is the dielectric constant of the semiconductor and R is radius of the vertical wire 112 (i.e. the radius of the p⁻ region in the vertical wire 112). The wire core radius R is given as: R=d/2−x_{J}, where d is the diameter of the pillar structure 120 and x_{J} is the junction depth or the thickness of the conformal semiconductor layer 114 (or emitter layer). The above equation (3) can be used to estimate the transition point B, which is useful when designing the capacitance profile of a wire-array varactor device according to principles of the invention. The ability to estimate transition point B is particularly useful in controlling the sensitivity of the C-V profile.

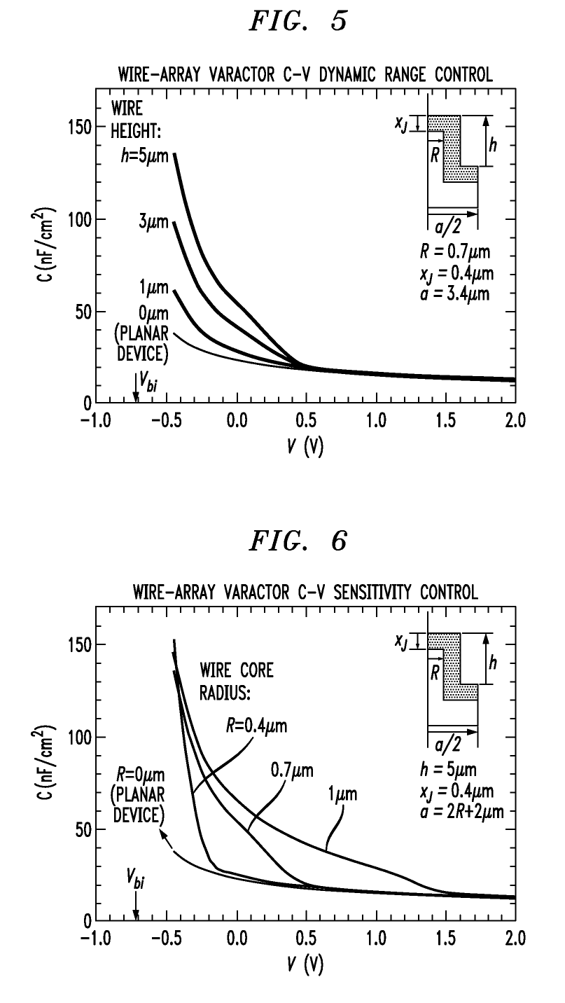

As noted above, various geometric parameters of the pillar structures can be adjusted to tune the C-V profile of a wire-array varactor device according to principles of the invention. In order to demonstrate tuning the C-V profile of a wire-array varactor device according to principles of the invention, computer simulations were performed based on a finite element calculation of a single wire varactor structure having the cylindrical symmetry model (as depicted in FIG. 3) using Comsol multiphysics. The computer simulations are depicted in FIGS. 5 and 6, which include C-V curves that calculated from the capacitance across the dielectric space charge region formed in the interface of the p-n junction using an abrupt junction model. FIG. 5 are C-V curves that illustrate dynamic range control of a wire-array varactor device for different height h values based on the unit cell geometric model of FIG. 3. Moreover, FIG. 6 are C-V curves that illustrate sensitivity control of a wire-array varactor device for different radius R values based on the unit cell geometric model of FIG. 3.

In particular, FIG. 5 illustrates a method for tuning the dynamic range of a wire array varactor device by adjusting the height h of the pillar structures 120. In FIG. 5, an inset shows the geometric parameters of the finite element simulation geometry that were fixed, i.e., R=0.7 μm, xⱼ=0.4 μm and a=3.4 μm, while varying the height parameter, i.e., h=0, 1, 3, and 5 μm. For the simulated C-V curves shown in FIG. 5, the parameters selected for the computer simulation were as follows: semiconductor material=silicon, N_{D}=5×10¹⁶/cm³, N_{A}=5×10¹⁵/cm³, nᵢ=5×10¹⁵/cm³, ε_{Si}=12ε₀, where ε₀ is the vacuum dielectric constant and T=300 K. Each of the C-V curves in FIG. 5 represent capacitance per unit area (nF/cm²) as a function of voltage V for the different height parameters h=0, 1, 3, and 5 μm. The C-V curve for h=0 μm essentially represents the C-V characteristics of a planar varactor device.

As further shown by the C-V curves in FIG. 5, the dynamic range of a wire-array varactor device according to principles of the invention can be increased by increasing the height h of the pillar structure. In particular, for larger values of h, the maximum capacitance increases with respect to h (in accordance with Equation (2) above), which increases the dynamic range (Cₘₐₓ/Cₘᵢₙ) of the varactor device. In example shown in FIG. 5, assuming that the voltage range is −0.45V to 4V, dynamic range as much as 13× can be obtained whereas conventional planar varactor typically provides dynamic range as much as 6× at maximum through tailoring the doping profile. Thus, a wire-array varactor device according to aspects of the invention can provide very high dynamic range.

Furthermore, FIG. 6 illustrates a method for tuning the sensitivity of a wire array varactor device by adjusting the inner radius R of the pillar structures 120. In FIG. 6, an inset shows the geometric parameters of the finite element simulation geometry that were fixed, i.e., h=5.0 μm and xⱼ=0.4 μm, while varying the radius parameter, i.e., R=0, 0.4, 0.7, and 1 μm and varying the parameter a as a function of R, i.e., by a=2 R+2 μm. For the simulated C-V curves shown in FIG. 6, the parameters selected for the computer simulation were as follows: semiconductor material=silicon, N_{D}=5×10¹⁶/cm³, N_{A}=5×10¹⁵/cm³, nᵢ=5×10¹⁵/cm³, ε_{Si}=12ε₀, where ε₀ is vacuum dielectric constant and T=300 K. Each of the C-V curves in FIG. 6 represent capacitance per unit area (nF/cm²) as a function of voltage V for the different radius parameters, i.e., R=0, 0.4, 0.7, and 1 μm. The C-V curve for R=0 μm essentially represents the C-V characteristics of a planar varactor device.

As further shown by the C-V curves in FIG. 6, the sensitivity of a wire-array varactor device according to principles of the invention can be increased by decreasing the inner radius R of the pillar structure. In particular, if the radius R parameter is reduced, the range of the cylindrical capacitance regime ΔV_{C} will be reduced by a factor of R² (in accordance with Equation (3)). With a smaller radius R, the change in capacitance occurs more rapidly, thus providing higher sensitivity. In the simulation results shown in FIG. 6, the emitter layer thickness x_{J} is kept constant. Therefore, smaller wire diameter of the wire-array varactor diode results in higher sensitivity of the device.

It is to be noted that the simulation results shown in FIGS. 5 and 6 include a C-V curve of a conventional planar varactor diode, which serves as reference baseline (obtained from the simulation in the limit of h=0 and R=0). The computer simulation results of FIGS. 5 and 6 show that the capacitance of a wire-array varactor device is larger than the planar capacitance in the low bias regime. In the high reverse bias regime, the wire-array capacitance will converge to the planar capacitance curves.

It is to be understood that the C-V profile of a wire-array varactor device according to principles of the invention may be tailored using other methods in addition to adjusting the h and R parameters as discussed above. For example, the C-V profile of a wire-array varactor device can be adjusted by, e.g., a non-uniform doping profile of the p-n junction, non-uniform distribution of heights and diameters of wires such that there is a combination of tall and thin wires and short and thick wires to achieve a specific C-V profile, and/or by non-uniform distribution of the lattice spacing/pitch.

It is to be appreciated that wire-array varactor devices according to principles of the invention can be fabricated using various techniques. For example, FIG. 7 are scanning electron microscope images of varactor devices fabricated using deep-UV lithography and self-assembled microsphere lithography. In particular, SEM images (a) and (b) in FIG. 7 illustrate a top-view and perspective side-view, respectively, of a wire-array varactor device that is formed using a deep-UV lithography process. In addition, SEM images (c) and (d) in FIG. 7 illustrate a top-view and perspective side-view, respectively, of a wire-array varactor device that is formed using a self-assembled microsphere lithography process. In accordance with exemplary embodiments of the invention, techniques disclosed in the following references: (1) Gunawan, et al, “High Performance Wire-Array Silicon Solar Cells”, Progress in Photovoltaics, (2010). DOI: 10.1002/pip.1027, and (2) copending and commonly owned U.S. patent application Ser. No. 12/480,163 (Publication No. 2010/0221866), may be used to fabricate wire-array varactor devices as described herein. Both references (1) and (2) are fully incorporated herein by reference.

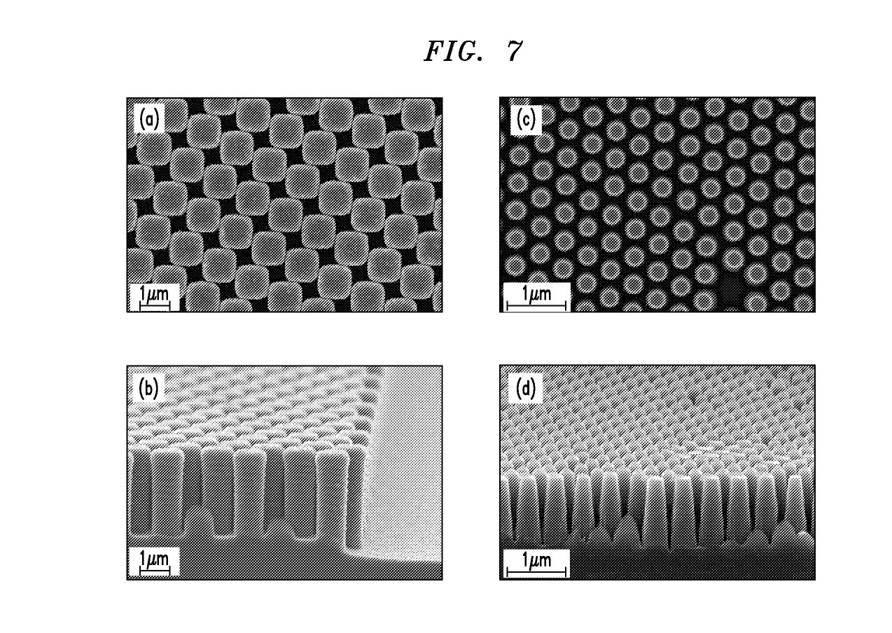

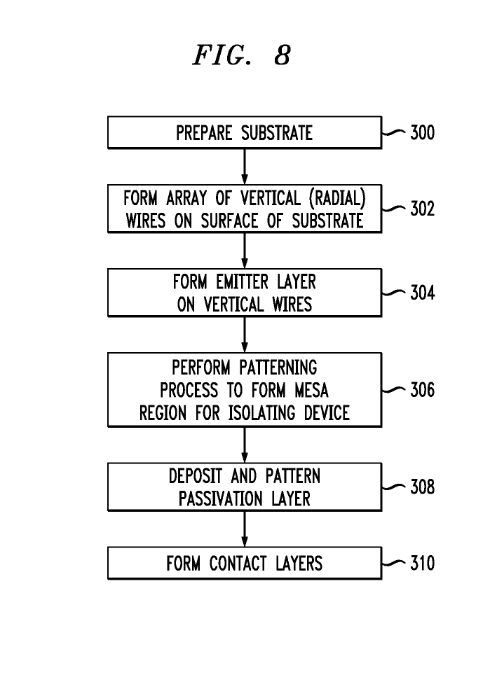

FIG. 8 is a flow diagram of a method for fabricating a wire-array varactor device according to one aspect of the invention. For purposes of illustration, the method of FIG. 8 will be described within the context of methods for fabricating the exemplary varactor structure 100 depicted in FIG. 1. An initial step in the exemplary fabrication process is to obtain a doped semiconductor substrate (step 300). The semiconductor substrate (e.g., substrate 110 as shown in FIG. 1) can be any semiconductor material, such as silicon, that is suitable for forming a p-n junction for a varactor device. The substrate 110 is doped with an n-type or a p-type dopant. Suitable n-type dopants include, but are not limited to phosphorous (P) and arsenic (As). Suitable p-type dopants include, but are not limited to boron (B). In one exemplary embodiment of the invention such as shown in FIG. 1, the substrate 110 may be a p-type silicon substrate (e.g., Si(100)) that is lightly doped.

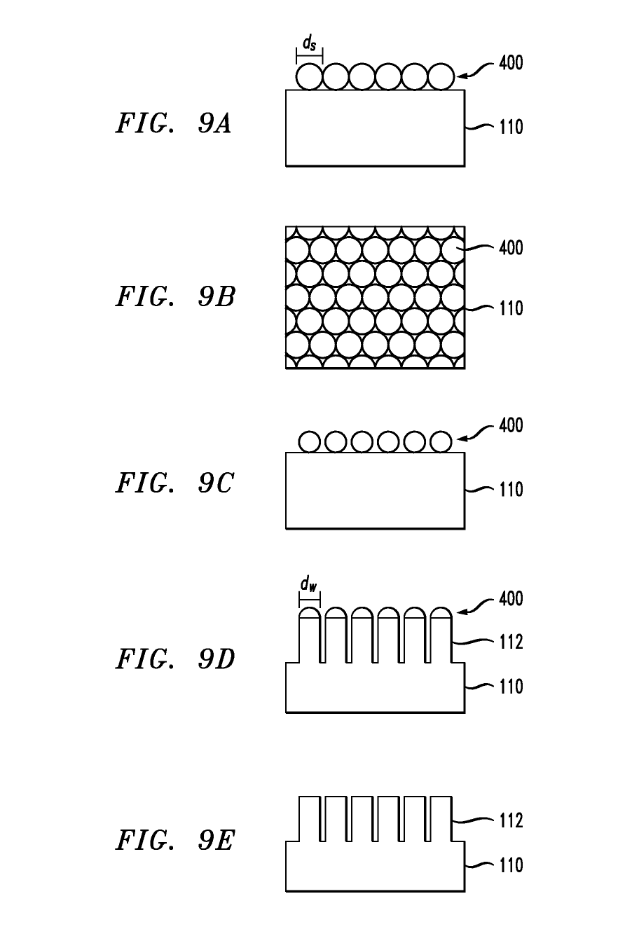

A next step is to form the array of vertical (radial) wires 112 on a surface of the substrate 110 (step 302). The array of vertical wires 112 may be foamed using various methods. For instance, in one exemplary embodiment of the invention, the array of vertical wires 112 can be fabricated using a conventional bottom-up technique such as VLS nanowire growth techniques where the nanowires are grown on the surface of the semiconductor substrate 110 using a chemical vapor deposition process and metal catalyst. In another exemplary embodiment, the array of vertical wires 112 can be fabricated by etching the surface of the substrate 110 using a standard photolithography process to define a mask pattern for etching the wires 112 and using the mask to etch down the exposed surface portions of the substrate 110 by deep reactive ion etching In another exemplary embodiment, the array of vertical wires 112 can be fabricated using a lower cost nano/microsphere lithography technique to create self-assembled monolayer of microsphere that serves as mask for the deep RIE etch process (as will be described in further detail below with reference to FIGS. 9A˜9E).

A next step in the exemplary fabrication process is to form the conformal semiconductor layer 114 (or emitter layer) over the vertical wires 112 and the substrate 110 (step 304). The emitter layer 114 is preferably a highly doped material layer with either an n-type or a p-type dopant, e.g., at a concentration of from about 1×10¹⁹ cubic centimeters (cm³) to about 1×10²¹ cm³, so as to have a polarity opposite to that of the substrate 110 and the vertical wires 112. By way of example only, if the vertical wires 112 are formed from a p-type Si substrate, then the emitter layer 114 would be doped with an n-type dopant to form a cylindrical p-n junction between wires 112 and emitter layer 114. The emitter layer 114 may be formed using one of various methods. For example, one method is by a drive-in diffusion technique and another method is by deposition.

More specifically, in one exemplary embodiment of the invention, the emitter layer 114 may be formed by diffusing an n-type or p-type dopant onto the vertical wires 112 from a dopant source. Suitable dopant sources include, but are not limited to, a spin-on-glass (SOG) dopant or a gas phase dopant precursor, such as phosphoryl chloride (POCl₃). For example, using a spin-on-glass (SOG) dopant source, the SOG is first deposited on the vertical wires 112 and the sample is then annealed for a drive-in diffusion step at a temperature of from about 850 degrees C. to about 1,000 degrees C., for a duration of from about 10 minutes to about 30 minutes (the duration depending on the targeted junction depth). For a gas phase dopant precursor, such as POCl₃, the vertical wires 112 are first exposed to the gas phase dopant precursor and the sample is then annealed at a temperature of about 800 degrees C. for a duration of about one hour (the duration can be adjusted accordingly to tune the junction depth).

The emitter layer 114 may be formed by deposition, wherein the emitter layer 114 is formed by conformally depositing a semiconductor material over the vertical wires 112 and substrate 110, wherein the semiconductor material would have a conductivity type opposite to that of the vertical wires 112 and substrate 110. For example, if the substrate is a p-type substrate one could deposit n-type Si or another n-type material(s), such as zinc oxide (ZnO) and/or ITO, on the vertical wires 112. According to an exemplary embodiment, the semiconductor material(s) is deposited on wires 112 using evaporation, sputtering or epitaxial growth. Evaporation, sputtering and epitaxial growth deposition techniques are known to those of skill in the art and thus are not described further herein. A varactor device with the emitter layer 114 formed in this manner (i.e., by deposition) guarantees conformal formation of a p-n junction on the nanowire/microwire surface which is desirable to obtain improved carrier collections in a radial direction. Specifically, with the (emitter layer) deposition process, the resulting p-n junction interface wraps around the nanowire/microwire surface, thus providing a radial p-n junction structure. Conformal formation of a p-n junction on the nanowire/microwire surface can also be obtained with the (emitter layer) diffusion process. However, tight and uniform control of the diffusion process is preferred. For example, control over the duration of the drive-in diffusion step is needed to prevent over/under diffusion which can negatively affect the p-n junction structure. In addition, using a deposition process to form the emitter layer 114 allows the emitter layer 114 to be formed with a material that is different from the material forming the substrate 110 and the vertical wires 112, which can be desirable for tuning the characteristics of the varactor device.

Referring again to FIG. 8, a next step in the exemplary fabrication process is to define the mesa structure 105 using standard patterning techniques, for example, to isolate the varactor device 100 (step 306). This process can be performed using suitable patterning techniques known to one of skill in the art. During this step, portions of emitter layer 114 are removed from those areas of substrate 110 that do not include the vertical wires 112. In addition, the surface of the substrate 110 in these regions is slightly recessed, as shown in FIG. 1.

A layer insulating material is then deposited and patterned to form the passivation (insulating) layer 150 surrounding the peripheral edges of the mesa region 105 of the device 100 (step 308). As noted above, the insulating layer 150 serves to minimize or prevent leakage of current along the peripheral edges of the mesa region 105 of the device 100 and prevent deterioration of the maximum capacitance. The insulating layer 150 may be formed of any suitable insulting/dielectric material such as SiO₂ and Si₃N₄ deposited and patterned using known techniques.

A next step in the exemplary fabrication process is to form the first contact layer 130 and the second contact layer 140 (step 310). The first and second contact layers 130 and 140 may be formed of metallic materials such as aluminum, copper, nickel, titanium, palladium, silver, or gold and conformally deposited using techniques such as metal evaporation, electroplating, or screen printing.

As noted above, in step 302 of the exemplary process of FIG. 8, the array of vertical wires 112 can be fabricated using a self-assembled nano/microsphere lithography process. FIGS. 9A, 9B, 9C, 9D, and 9E illustrate an exemplary methodology for fabricating a wire array varactor device using a self-assembled nano/microsphere lithography process according to an aspect of the invention. As shown in FIG. 9A, a monolayer of spheres 400 are deposited on the substrate 110. FIG. 9B is a top schematic view of FIG. 9A, showing an arrangement of the monolayer of spheres 400 deposited on the substrate 110. The spheres 400 include nanospheres, microspheres or a combination of nanospheres and microspheres. Nanospheres are generally considered herein to include spheres 400 having a diameter d_{S} of less than about one micron, e.g., from about 50 nanometers (nm) to about one micrometer. Microspheres are generally considered herein to include spheres 400 having a diameter d_{S} of greater than or equal to about one micron, e.g., in a range from about one micron to about 50 microns. The spheres 400 are used to pattern vertical wires 112 in the substrate 112 with the diameters of the wires being dependent on the diameters of the spheres following a trimming step (as discussed below), wherein the post-trimming nanospheres, microspheres or a combination of nanospheres and microspheres will be used to pattern the vertical wires 112 in the substrate. According to an exemplary embodiment, commercially available polystyrene latex spheres may be used. The nanospheres and/or microspheres may be deposited using known methods, such as described in the above incorporated patent application U.S. patent application Ser. No. 12/480,163 (Publication No. 2010/0221866).

Next, as shown in FIG. 9C, the spheres 400 are trimmed to introduce space between the individual spheres in the monolayer. According to an exemplary embodiment, oxygen (O₂) plasma reactive ion etching (RIE) may be used to trim the diameters of the spheres. The amount of trimming (how much the diameters of the spheres are trimmed/reduced) is controlled by controlling the timing of the plasma etch. This trimming step is performed to allow sufficient interstitial space in between the later-formed nanowires and/or microwires to accommodate for the formation of the emitter layer. The trimming step also serves to reduce the nanospheres and/or microspheres to the proper size (i.e., diameter) for wire patterning. By way of example only, if the monolayer of spheres 400 contains only microspheres and patterning of nanowires in the substrate is desired, then the trimming step can be used to reduce the diameters of the spheres to the desired nanometer size. This reduction in size of the spheres as a result of the trimming step has to be taken into account when assessing the starting sphere size (pre-trimming) and the desired wire diameter.

Next, as shown in FIG. 9D, the trimmed spheres 400 (with reduced diameters) are used as masks to pattern the vertical wires 112 in the substrate 110. According to an exemplary embodiment, vertical wires 112 are patterned in substrate 110 using a deep RIE process. For example, when substrate 110 comprises silicon (Si), hydrobromic acid (HBr), tetrafluoromethane (CF₄) and chlorine gas (Cl₂) chemistry or BOSCH process (e.g., a time-multiplexed RIE process consisting of etching step with sulfur hexafluoride (SF₆) and a passivation step with octafluorocyclobutane (C₄F₈)) may be used. It is also possible to utilize a wet etching technique to avoid vacuum processing and lower the cost. While wet etching techniques make use of a metal catalyst, such as Ag, the metal is only used as an etching catalyst, not as a growth catalyst, therefore it is less likely to be incorporated into the semiconductor material. So it is possible that any detrimental effects of the metal are minimal.

It is to be noted that the diameters of the vertical wires 112 patterned in substrate 110 are dependent on the post-trimming diameters of spheres 400. Thus, post-trimming, nanospheres, microspheres, or a combination of nanospheres and microspheres will result in nanowires, microwires or a combination of nanowires and microwires, respectively, being patterned substrate 110. Accordingly, nanowires are generally considered herein to include vertical wires 112 having a diameter d_{w} of less than about one micron, e.g., from about 50 nm to about one micron. Microwires are generally considered herein to include vertical wires 112 having a diameter d_{w} of greater than or equal to about one micron, e.g., from about one micron to about 50 microns. The vertical wires 112 now patterned in substrate 110 may be cleaned to remove any surface damage due to the RIE process. For Si substrates, for example, an oxidation step (using a solution of sulfuric acid and hydrogen peroxide) followed by an RCA clean may be used. The steps performed in an RCA clean are known to those of skill in the art and thus are not described further herein. During this cleaning step, the residual spheres are removed, resulting in the structure shown in FIG. 9E.

It is to be understood that the invention is not limited to the particular materials, features, and processing steps shown and described herein. Modifications to the illustrative embodiments will become apparent to those of ordinary skill in the art. It should also be understood that the various layers and/or regions shown in the accompanying figures are not drawn to scale, and that one or more semiconductor layers and/or regions of a type commonly used in such integrated circuits may not be explicitly shown in a given figure for ease of explanation. Particularly with respect to processing steps, it is to be emphasized that the descriptions provided herein are not intended to encompass all of the processing steps that may be required to form a functional integrated semiconductor device. For convenience of explanation and not intended to be limiting, the semiconductor devices and methods of fabrication are described herein for silicon semiconductors but persons of ordinary skill in the art will understand that other semiconductor materials can also be used. Further, even though the present invention is illustrated for the case of a p-n junction varactor diode, those of ordinary skill in the art will understand that the present invention applies to any type of rectifying device providing a voltage variable capacitance and whose depletion width depends upon the doping of the semiconductor and the applied voltage. Non-limiting examples are p-n junction diodes, metal-semiconductor diodes and hetero junction diodes. As used herein the term “metal” is intended to include semi-metals, semiconductor-metal alloys and other materials that are relatively more conductive than the associated semiconductor body.

The present invention described herein is illustrated by semiconductor devices and structures of particular conductivity type having P and N doped regions appropriate for that conductivity type device and structure. But this is merely for convenience and is not intended to be limiting. Persons of skill in the art will understand that devices or structures of opposite conductivity type may be provided by interchanging conductivity types so that a P-type region becomes an N-type region and vice versa. Alternatively, the particular regions may be more generally referred to as of a “first conductivity type” and a “second, opposite conductivity type” where the first conductivity type may be either P or N type and the second opposite conductivity type may be either N or P type.

Further aspects of the present invention provide varactor devices that can be utilized in integrated circuit chips with various analog and digital integrated circuitries. In particular, integrated circuit dies can be fabricated having varactor devices and other semiconductor devices such as field-effect transistors, bipolar transistors, metal-oxide-semiconductor transistors, diodes, resistors, capacitors, inductors, etc., forming analog and/or digital circuits. The varactor devices can be formed upon or within a semiconductor substrate, the die also comprising the substrate. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of this invention. Given the teachings of the invention provided herein, one of ordinary skill in the art will be able to contemplate other implementations and applications of the techniques of the invention.

Although exemplary embodiments of the present invention have been described herein with reference to the accompanying figures, it is to be understood that the invention is not limited to those precise embodiments, and that various other changes and modifications may be made therein by one skilled in the art without departing from the scope of the appended claims.

What is claimed is:

1. A method of fabricating a semiconductor varactor device, comprising:
forming an array of pillar structures on a first surface of a doped semiconductor substrate, wherein each pillar structure comprises a radial p-n junction structure;
conformally forming a first metallic contact layer over the array of pillar structures on the first surface of the doped semiconductor substrate;
forming a second metallic contact layer on a second surface of the doped semiconductor substrate opposite the first surface; and
forming an insulating layer on the doped semiconductor substrate surrounding the array of pillar structures.

2. The method of claim 1, wherein forming the array of pillar structures comprises forming a honeycomb lattice arrangement of pillar structures.

3. The method of claim 1, wherein forming the array of pillar structures comprises:
forming an array of radial wires on the first surface of the doped semiconductor substrate;
forming a conformal semiconductor layer on the array of radial wires and on regions of the first surface of the doped semiconductor substrate between the radial wires.

4. The method of claim 3, wherein the doped semiconductor substrate and the radial wires have a first conductivity type, and wherein the doped conformal semiconductor layer has a second conductivity type.

5. The method of claim 4, further comprising selecting dopant concentrations of the semiconductor substrate and radial wires, and of the doped conformal semiconductor layer such that a dielectric depletion region is formed within the material forming the radial wires and in regions of the semiconductor substrate between the pillars.

6. The method of claim 4, wherein the first conductivity type is p- and wherein the second conductivity type is n+.

7. The method of claim 1, wherein the pillar structures are cylindrical shaped.

8. The method of claim 7, wherein the pillar structures,have a diameter d and a height h, wherein the method further comprises selecting values of d and h to tune capacitance-voltage characteristics of the semiconductor varactor device.

9. The method of claim 8, wherein a sensitivity characteristic of the varactor device is tunable based on the parameter h.

10. The method of claim 8, wherein a dynamic range characteristic of the varactor device is tunable based on the parameter d.
